(19) United States
(12) Patent Application Publication
(10) Pub. No.: US 2019/0131207 A1
(43) Pub. Date: May 2, 2019

(54) A HEAT SINK, A FILLER FOR A HEAT SINK AND METHODS THEREOF

(71) Applicant: REPUBLIC POLYTECHNIC, Singapore (SG)

(72) Inventor: Santhiagu EZHILVALAVAN, Singapore (SG)

(21) Appl. No.: 16/099,854

(22) PCT Filed: May 9, 2017
(86) PCT No.: PCT/SG2017/050240

§ 371 Date: Nov. 8, 2018

(30) Foreign Application Priority Data
May 10, 2016 (SG) 10201603695U

(51) Int. Cl. H01L 23/373; C08K 3/04; C08K 3/013; C09K 5/14; C08K 13/04

(52) U.S. Cl. CPC H01L 23/3731; C08K 3/04; C08K 3/013; C08K 2201/005; C09K 5/14; C08K 13/04; H01L 23/3737

(57) ABSTRACT

A formulation for a heat sink, a filler composition for a heat sink, and methods of making thereof are provided, the filler composition comprising a first ceramic filler having a volume electrical resistivity of at least 10⁶ Ω-cm; a second filler having a volume electrical resistivity of less than 10⁵ Ω-cm; a third filler having an electrical conductivity of more than 60,000 S/m; and a fourth filler having a breaking strength of more than 200 MPa.

### TECHNICAL FIELD

Various embodiments disclosed herein relate broadly to a formulation for a heat sink, a filler composition for a heat sink, and methods of making thereof.

### BACKGROUND

The trend of shrinking sizes, increase in circuit density and functionality in today's electronic and opto-electronic devices have led to severe thermal management problems and poses significant challenges to their reliability. The power density, and corresponding density of heat that needs to be dissipated, have significantly increased with the prevalence of personal hand-held electronic devices, light emitting diodes (higher lumen output), electronic components in automobiles, rechargeable high density battery systems and power inverters for hybrid vehicles. Insufficient or ineffective thermal management can have a strong and deleterious effect on the performance and long-term reliability of the devices.

In various manufacturing industries, metallic materials have been employed as heat sinks for heat absorption and dissipation. Metallic heat sinks are tooled or machined from bulk metals into desired configurations and are typically very heavy, expensive to fabricate and susceptible to corrosion. Further, the geometries of machined metal heat sinks are very limited due to the inherent limitations associated with machining or tooling techniques. The trend to miniaturize various electronic components and devices dictates that heat sinks follow such miniaturization trends to provide aesthetic appeal to the end product. As a result of the smaller dimensions of the device inclusive of packaging, formation of hot-spots becomes more severe with poor heat dissipation characteristics, which, in turn, may lead to degradation of device performance, erratic behaviour, a shortened life span, and other possible undesirable consequences. Many other applications also require thermally conducting and electrically insulating requirements for which metal heat sinks are not suitable.

Heat sinks made from plastics are attractive alternatives to metal, as they are electrically insulating, light in weight, easy to fabricate into complex designs using injection moulding techniques, and offer the possibility of integrating several parts together, for example, as a LED light holder which also provides heat sink functions, a high density battery casing which also provides heat sink functions, etc. However, plastics have poor thermal conductivity (less than 0.5 W/mK) in comparison to metals (aluminium ˜200 W/mK; copper ˜400 W/mK).

To address the above mentioned issues related to the use of metal heat sinks, attempts have been made to provide thermally conductive moulded plastic compositions that include conductive filler particles and insulative binder resins. Typically, the concentration of conductive filler particles exceed more than 60% by volume. However, this leads to problems such as filler aggregation, non-uniform distribution, difficulty to fabricate into complex shapes or sizes and increased production cost. Loading higher volume of conductive filler particles also leads to increased electrical conductivity which is undesirable for many applications.

Thus, there is a need for a formulation for a heat sink, a filler composition for a heat sink, and method of making such formulation/composition that seek to address or at least ameliorate one of the above problems.

### SUMMARY

In accordance with a first aspect of the present disclosure, there is provided a filler composition for a heat sink, the filler composition comprising a first ceramic filler having a volume electrical resistivity of at least 10⁶ Ω-cm; a second filler having a volume electrical resistivity of less than 10⁵ Ω-cm; a third filler having an electrical conductivity of more than 60,000 S/m; and a fourth filler having a breaking strength of more than 200 MPa.

The first filler may be present in an amount from 1.0% to 25.0% by weight of the filler composition; the second filler may be present in an amount from 1.0% to 25.0% by weight of the filler composition; the third filler may be present in an amount from 1.0% to 25.0% by weight of the filler composition; and the fourth filler may be present in an amount from 1.0% to 25.0% by weight of the filler composition.

The first filler may have an intrinsic thermal conductivity of 10 W/mK to 50 W/mK; and the second, third and fourth fillers may have an intrinsic thermal conductivity of more than 100 W/mK.

The first ceramic filler may be in the form of powder, agglomerates or fibres having an average particle size of 0.05 μm to 1000 μm.

The first filler may comprise one or more ceramic fillers selected from the group consisting of boron nitride (BN), aluminium nitride (AlN), titanium nitride (TiN), aluminium oxide (Al₂O₃), zinc oxide (ZnO) and silicon carbide (SiC).

The second filler may comprise one or more material selected from the group consisting of graphite, graphene, graphitized carbon black, carbon fibre and carbon nanotubes (CNT).

The second filler may be in the form of flakes, sheets or fibres, having an aspect ratio of at least 25:1.

The third filler may comprise one or more material selected from the group consisting of graphite, graphene, graphitized carbon black, carbon fibre and carbon nanotubes (CNT).

The third filler may be in the form of nanoplatelets having a diameter of 1 μm to 20 μm and a thickness of 2 nm to 20 nm.

The fourth filler may have a volume electrical resistivity of less than 10⁻³ Ω-cm.

The fourth filler may comprise one or more material selected from the group consisting of carbon fibre, carbon nanotubes (CNT), gold, silver, copper and nickel.

The fourth filler may be in the form of flakes, sheets or particles having a diameter/particle size/thickness from 1 μm to 20 μm, or in the form of fibres having a length of more than 10 μm.

In accordance with a second aspect of the present disclosure, there is provided a method of making a filler composition as disclosed herein, the method comprising, providing a first ceramic filler having a volume electrical resistivity of at least 10⁶ Ω-cm in an amount from 1.0% to 25.0% by weight of the filler composition; providing a second filler having a volume electrical resistivity of less than 10⁵ Ω-cm in an amount from 1.0% to 25.0% by weight of the filler composition; providing a third filler having an electrical conductivity of more than 60,000 S/m in an amount from 1.0% to 25.0% by weight of the filler composition; and providing a fourth filler having a breaking strength of more than 200 MPa in an amount from 1.0% to 25.0% by weight of the filler composition.

In accordance with a third aspect of the present disclosure, there is provided a formulation for a heat sink, the formulation comprising, a polymer matrix present in an amount from 25% to 75% by weight of the formulation; a filler composition as disclosed herein, present in an amount from 25% to 75% by weight of the formulation; and a surface modifying agent present in an amount from 0.1% to 5% by weight of the formulation.

The formulation may have a cross-plane thermal conductivity of at least 50 W/mK.

The formulation may have a tensile strength of more than 20 MPa, a Young's modulus of more than 0.5 GPa and a Shore D hardess of more than 70.

The polymer matrix may comprise a thermoplastic polymer having a thermal conductivity of at least 0.17 W/mK.

The thermoplastic polymer may have a volume electrical resistivity at least 10¹⁵ Ω-cm.

The thermoplastic polymer may be an amorphous material having a glass transition temperature (T_{g}) of at least −80° C., or a crystalline material having a melting point (Tₘ) of at least 100° C.

The thermoplastic polymer may have a tensile strength of at least 20 MPa, and a Young's modulus of at least 1 GPa.

### Definitions

The term “thermal conductivity” as used herein is the property of a material to conduct/dissipate heat. Thermal conductivity (K) is one of the basic thermophysical properties which determine the heat flux and the resulting temperature field in a device configuration, subject to boundary conditions and material properties.

Thermal conductivity (k) in Watts per meter Kelvin (W/mK) is defined as

K=ρCₚα Equation (1)

where α is the thermal diffusivity (cm²/s), ρ is the density (kg/cm³) and Cₚ is the specific heat capacity (J/kgK) of the heat sink material.

The term “electrical conductivity” as used herein is the property of a material to conduct an electric current. Electrical conductivity as used herein may be used to describe a conductive material, which is intrinsically or inherently capable of electrical conductivity, and a semiconductive material, which exhibits semiconducting properties.

The term “volume electrical resistivity” as used herein is the property of a material which measures how strongly the material opposes the flow of electric current.

The term “in plane” as used herein refers to the plane that is substantially parallel to a bonded surface of a heat sink.

The term “through plane” as used herein refers to the direction that is substantially orthogonal to an in-plane surface.

The term “thermoplastic” as used herein refers to a material that can be repeatedly softened by exposure to heat and hardened by cooling. In the softened state, the thermoplastic become pliable or moldable and can be shaped into articles by processing techniques, e.g., by molding or extrusion.

The term “layer” when used to describe a first material is to be interpreted broadly to refer to a first depth of the first material that is distinguishable from a second depth of a second material. The first material of the layer may be present as a continuous film, as discontinuous structures or as a mixture of both. The layer may also be of a substantially uniform depth throughout or varying depths. Accordingly, when the layer is formed by individual structures, the dimensions of each of individual structure may be different. The first material and the second material may be same or different and the first depth and second depth may be same or different.

The term “continuous” when used to describe a film or a layer is to be interpreted broadly to refer to a film or a layer that is substantially without gaps or holes or voids across the film or layer. In this regard, a continuous film or a continuous layer is also intended to include a film or a layer that may have trivial gaps or holes or voids that may not appreciably affect the desired properties of the film or the layer.

The term “micro” as used herein is to be interpreted broadly to include dimensions from about 1 micron to about 1000 microns.

The term “nano” as used herein is to be interpreted broadly to include dimensions less than about 1000 nm.

The term “particle” as used herein broadly refers to a discrete entity or a discrete body. The particle described herein can include an organic or an inorganic particle. The particle used described herein may also be a macro-particle that is formed by an aggregate of a plurality of sub-particles or a fragment of a small object. The particle of the present disclosure may be spherical, substantially spherical, or non-spherical, such as irregularly shaped particles or ellipsoidally shaped particles. The term “size” when used to refer to the particle broadly refers to the largest dimension of the particle. For example, when the particle is substantially spherical, the term “size” can refer to the diameter of the particle; or when the particle is substantially non-spherical, the term “size” can refer to the largest length of the particle.

The terms “coupled” or “connected” as used in this description are intended to cover both directly connected or connected through one or more intermediate means, unless otherwise stated.

The term “associated with”, used herein when referring to two elements refers to a broad relationship between the two elements. The relationship includes, but is not limited to a physical, a chemical or a biological relationship. For example, when element A is associated with element B, elements A and B may be directly or indirectly attached to each other or element A may contain element B or vice versa.

The term “adjacent” used herein when referring to two elements refers to one element being in close proximity to another element and may be but is not limited to the elements contacting each other or may further include the elements being separated by one or more further elements disposed therebetween.

The term “and/or”, e.g., “X and/or Y” is understood to mean either “X and Y” or “X or Y” and should be taken to provide explicit support for both meanings or for either meaning.

Further, in the description herein, the word “substantially” whenever used is understood to include, but not restricted to, “entirely” or “completely” and the like. In addition, terms such as “comprising”, “comprise”, and the like whenever used, are intended to be non-restricting descriptive language in that they broadly include elements/components recited after such terms, in addition to other components not explicitly recited. Further, terms such as “about”, “approximately” and the like whenever used, typically means a reasonable variation, for example a variation of +/−5% of the disclosed value, or a variance of 4% of the disclosed value, or a variance of 3% of the disclosed value, a variance of 2% of the disclosed value or a variance of 1% of the disclosed value.

Furthermore, in the description herein, certain values may be disclosed in a range. The values showing the end points of a range are intended to illustrate a preferred range. Whenever a range has been described, it is intended that the range covers and teaches all possible sub-ranges as well as individual numerical values within that range. That is, the end points of a range should not be interpreted as inflexible limitations. For example, a description of a range of 1% to 5% is intended to have specifically disclosed sub-ranges 1% to 2%, 1% to 3%, 1% to 4%, 2% to 3% etc., as well as individually, values within that range such as 1%, 2%, 3%, 4% and 5%. The intention of the above specific disclosure is applicable to any depth/breadth of a range.

### DESCRIPTION OF EMBODIMENTS

Exemplary, non-limiting embodiments of a formulation for a heat sink, a filler composition for a heat sink, and a method of making the formulation and filler composition are disclosed hereinafter.

In various embodiments, a formulation for a heat sink is provided. The formulation comprises a polymer matrix present in an amount from about 25% to about 75% by weight (of the heat sink), a filler composition present in an amount from about 25% to 75% by weight (of the heat sink), and coupling agents such as surface modification agents. The filler composition may be a set of hybrid fillers.

Advantageously, embodiments of the formulation disclosed herein provides a cost effective moldable thermoplastic heat sink that displays excellent thermal conductivity, mechanical strength, heat resistance and electrical resistance. The polymer matrix e.g. thermoplastics, fillers and coupling agents can be melt processed using a hot-melt mixer and custom-designed heat sink components can be fabricated in high speed, high volume injection molding component.

The plastic heat sink formed from embodiments of the formulation as disclosed herein displays a high cross-plane thermal conductivity of from about 4 W/mK to about 52 W/mK. In addition to displaying a high cross-plane thermal conductivity, the heat sink also exhibit desirable mechanical, thermal and heat absorption and dissipation characteristics such as enhanced tensile strength of more than 65 MPa; Young's Modulus of more than 1.4 Gpa; Shore D Hardness of more than 75, better resistance to heat (i.e. able to withstand 150° C. or higher) and efficient heat dissipation characteristics (i.e. about 50% loss of absorbed heat in less than 60 s).

In various embodiments, a polymer matrix material is provided. The polymer matrix material may include any thermoplastic polymer or resin material as desired for a particular or intended application.

In various embodiments, the formulation for a heat sink comprises of a polymer matrix. The polymer matrix is present in the heat sink in an amount from about 25% to about 75% by weight of the formulation, from about 30% to about 70% by weight of the formulation, from about 35% to about 65% by weight of the formulation, from about 40% to about 60% by weight of the formulation, from about 45% to about 55% by weight of the formulation, or from about 50% to about 55% by weight of the formulation.

In various embodiments, the polymer matrix has a thermal conductivity of at least 0.05 W/mK, at least 0.10 W/mK, at least 0.15 W/mK, at least 0.20 W/mK, at least 0.25 W/mK, at least 0.30 W/mK, at least 0.35 W/mK, at least 0.40 W/mK, at least 0.45 W/mK, or at least 0.50 W/mK.

In one embodiment, the polymer matrix has a thermal conductivity of at least 0.17 W/mK.

In various embodiments, the polymer matrix has a tensile strength of at least 5 MPa, at least 10 MPa, at least 15 MPa, at least 20 MPa, at least 25 MPa, at least 30 MPa. In various embodiments, the polymer matrix displays a Young's modulus value of at least 0.2 GPa, at least 0.4 GPa, at least 0.6 GPa, at least 0.8 GPa, at least 1.0 GPa, at least 1.2 GPa, at least 1.4 GPa, at least 1.6 GPa, at least 1.8 GPa, or at least 2.0 GPa.

In one embodiment, the polymer matrix has a tensile strength of at least 20 MPa with a Young's modulus value of at least 1 GPa.

In various embodiments, the polymer matrix material has a volume electrical resistivity of at least 10¹³ Ohm-cm (Ω-cm), at least 10¹⁴ Ohm-cm, at least 10¹⁵ Ohm-cm, at least 10¹⁶ Ohm-cm, or at least 10¹⁷ Ohm-cm.

In one embodiment, the polymer matrix material has a volume electrical resistivity of at least 10¹⁵ Ohm-cm.

In various embodiments, the polymer matrix comprises an amorphous material with a glass transition temperature T_{g} of at least −60° C., at least −65° C., at least −70° C., at least −75° C., at least −80° C., at least −85° C., at least −90° C., at least −95° C., or at least −100° C.

In one embodiment, the polymer matrix comprises an amorphous material with a glass transition temperature T_{g} of at least −80° C.

In various embodiments, the polymer matrix comprises a crystalline material with a melting temperature Tₘ of at least 80° C., at least 85° C., at least 90° C., at least 95° C., at least 100° C., at least 105° C., at least 110° C., at least 115° C., or at least 120° C.

In one embodiment, the polymer matrix comprises a crystalline material with a melting temperature Tₘ of at least 100° C.

In various embodiments, the polymer matrix comprises thermoplastic polymers which include but are not limited to High Density Polyethylene (HDPE), Polycarbonate (PC), Acrylonitrile butadiene styrene (ABS), PC-ABS alloys, Polyphenylene sulphide (PPS), Polyether imide (PEI), Polyether ketone (PEEK), Polystyrene (PS), Polyvinyl chloride (PVC), Polyvinylidene fluoride (PVDF) and Perfluoroalkoxy alkanes (PFA) or a combination thereof.

In various embodiments, a filler composition comprising a blend of fillers is provided. The filler composition comprises of a first filler TCF1, a second filler TCF2, a third filler TCF3 and a fourth reinforcing filler TCRF4. The filler composition may comprise TCF1 in an amount of about 1.0% to about 25.0% by weight of the filler composition, TCF 2 in an amount of about 1.0% to about 25.0% by weight of the filler composition, TCF3 of about 1.0% to about 25.0% by weight of the filler composition, and TCRF4 of about 1.0% to about 25.0% by weight of the filler composition.

In various embodiments, a first filler TCF1 is provided in a filler composition comprising a blend of fillers. The first filler TCF1 is configured to be thermally conductive and electrically insulative, and may be a ceramic filler in the form of powder, agglomerates or fibres. The first filler TCF1 may be a crystalline or amorphous material.

In various embodiments, the first filler TCF1 has an average particle size of from about 0.05 μm to about 1000 μm, from about 0.5 μm to about 900 μm, from about 1 μm to about 800 μm, from about 10 μm to about 700 μm, from about 20 μm to about 600 μm, from about 50 μm to about 500 μm, from about 100 μm to about 400 μm, or from about 200 μm to about 300 μm.

In one embodiment, the first filler TCF1 has an average particle size of from about 0.05 μm to about 1000 μm.

In various embodiments, the first filler TCF1 has an intrinsic thermal conductivity of from about 5 W/mK to about 50 W/mK, from about 10 W/mK to about 45 W/mK, from about 15 W/mK to about 40 W/mK, from about 20 W/mK to about 35 W/mK, or from about 25 W/mK to about 30 W/mK.

In one embodiment, the first filler TCF1 has an intrinsic thermal conductivity of from about 10 W/mK to about 50 W/mK.

In various embodiments, the first filler TCF1 has a volume electrical resistivity of at least 10³ Ohm-cm, at least 10⁴ Ohm-cm, at least 10⁵ Ohm-cm, at least 10⁶ Ohm-cm, or at least 10⁷ Ohm-cm.

In one embodiment, the first filler TCF1 has a volume electrical resistivity of about 10⁶ Ohm-cm.

In various embodiments, the first filler TCF1 includes but is not limited to boron nitride (BN), aluminium nitride (AlN), titanium nitride (TiN), aluminium oxide (Al₂O₃), zinc oxide (ZnO), silicon carbide (SiC) or a combination thereof.

In one embodiment, the first filler TCF1 consists one or more materials selected from the group consisting of boron nitride (BN), aluminium nitride (AlN), titanium nitride (TiN), aluminium oxide (Al₂O₃), zinc oxide (ZnO), and silicon carbide (SiC).

In various embodiments, the first filler TCF1 is present in a heat sink in an amount from about 1% to about 10% by weight of the heat sink, from about 2% to about 10% by weight of the heat sink, from about 4% to about 10% by weight of the heat sink, from about 6% to about 10% by weight of the heat sink, or from about 8% to about 10% by weight of the heat sink.

In various embodiments, a second filler TCF2 is provided in a filler composition comprising a blend of fillers. The second filler TCF2 is configured to be thermally and electrically conductive with relatively higher surface area or aspect ratio. The second filler TCF2 may be in the form of flakes, sheets, or fibres.

In various embodiments, the second filler TCF2 has an aspect ratio of at least 5:1, at least 6:1, at least 7:1, at least 8:1, at least 9:1, at least 10:1, at least 15:1, at least 20:1, at least 25:1, at least 30:1, at least 35:1, at least 40:1, at least 45:1, or at least 50:1.

In one embodiment, the second filler TCF2 has an aspect ratio of at least 25:1.

In various embodiments, the second filler TCF2 has an intrinsic thermal conductivity of at least 50 W/mK, at least 55 W/mK, at least 60 W/mK, at least 65 W/mK, at least 70 W/mK, at least 75 W/mK, at least 80 W/mK, at least 85 W/mK, at least 90 W/mK, at least 95 W/mK, at least 100 W/mK, at least 105 W/mK, at least 110 W/mK, at least 115 W/mK, or at least 120 W/mK.

In one embodiment, the second filler TCF2 has an intrinsic thermal conductivity of more than 100 W/mK.

In various embodiments, the second filler TCF2 has a volume electrical resistivity of less than 10 Ohm-cm, less than 10² Ohm-cm, less than 10³ Ohm-cm, less than 10⁴ Ohm-cm, or less than 10⁵ Ohm-cm.

In one embodiment, the second filler TCF2 has a volume electrical resistivity of less than 10⁴ Ohm-cm.

In various embodiments, the second filler TCF2 includes but is not limited to graphite, graphene, graphitized carbon black, carbon fibre, carbon nanotubes (CNT) or a combination thereof.

In one embodiment, the second filler TCF2 consists one or more materials selected from the group consisting of graphite, graphene, graphitized carbon black, carbon fibre, and carbon nanotubes (CNT).

In various embodiments, the composition for a heat sink comprises a second filler TCF2. The second filler TCF2 is present in the heat sink in an amount from about 1% to about 10% by weight of the heat sink, from about 2% to about 10% by weight of the heat sink, from about 4% to about 10% by weight of the heat sink, from about 6% to about 10% by weight of the heat sink, or from about 8% to about 10% by weight of the heat sink.

In various embodiments, a third filler TCF3 is provided in a filler composition comprising a blend of fillers. The third filler TCF3 is configured to be thermally and electrically conductive with a relatively higher surface area or aspect ratio. The third filler TCF3 may be in the form of nanoplatelets.

In various embodiments, the third filler TCF3 in the form of nanoplatelets having an average diameter of from about 0.5 μm to about 25 μm, from about 1 μm to about 24 μm, from about 2 μm to about 24 μm, from about 4 μm to about 22 μm, from about 6 μm to about 20 μm, from about 8 μm to about 18 μm, from about 10 μm to about 16 μm, or from about 12 μm to about 14 μm.

In various embodiments, the third filler TCF3 in the form of nanoplatelets has a thickness of from about 1 nm to about 22 nm, from about 2 nm to about 20 nm, from about 4 nm to about 18 nm, from about 6 nm to about 16 nm, from about 8 nm to about 14 nm, or from about 10 nm to about 12 nm.

In one embodiment, the third filler TCF3 in the form of nanoplatelets has an average diameter of from about 1 μm to about 20 μm and a thickness of from about 2 nm to about 20 nm.

In various embodiments, the third filler TCF3 has an aspect ratio of at least 5:1, at least 6:1, at least 7:1, at least 8:1, at least 9:1, at least 10:1, at least 15:1, at least 20:1, at least 25:1, at least 30:1, at least 35:1, at least 40:1, at least 45:1, or at least 50:1.

In one embodiment, the third filler TCF3 has an aspect ratio of at least 25:1.

In various embodiments, the third filler TCF3 has an intrinsic thermal conductivity of at least 50 W/mK, at least 55 W/mK, at least 60 W/mK, at least 65 W/mK, at least 70 W/mK, at least 75 W/mK, at least 80 W/mK, at least 85 W/mK, at least 90 W/mK, at least 95 W/mK, at least 100 W/mK, at least 105 W/mK, at least 110 W/mK, at least 115 W/mK, or at least 120 W/mK.

In one embodiment, the third filler TCF3 has an intrinsic thermal conductivity of more than 100 W/mK.

In various embodiments, the third filler TCF3 has an electrical conductivity of more than 10,000 S/m, more than 20,000 S/m, more than 30,000 S/m, more than 40,000 S/m, more than 50,000 S/m, more than 60,000 S/m, more than 70,000 S/m, more than 80,000 S/m, or more than 90,000 S/m.

In one embodiment, the third filler TCF3 has an electrical conductivity of more than 60,000 S/m.

In various embodiments, the third filler TCF3 includes but is not limited to graphite, graphene, graphitized carbon black, carbon fibre, carbon nanotubes (CNT) or a combination thereof.

In one embodiment, the third filler TCF3 consists one or more materials selected from the group consisting of graphite, graphene, graphitized carbon black, carbon fibre, and carbon nanotubes (CNT).

In various embodiments, the third filler TCF3 is present in a heat sink in an amount from about 1% to about 10% by weight of the heat sink, from about 2% to about 10% by weight of the heat sink, from about 4% to about 10% by weight of the heat sink, from about 6% to about 10% by weight of the heat sink, or from about 8% to about 10% by weight of the heat sink.

In various embodiments, a fourth reinforcing filler TCRF4 is provided in a filler composition comprising a blend of fillers. The fourth reinforcing filler TCRF4 is configured to be thermally and electrically conductive with relatively higher mechanical strength.

In various embodiments, the fourth reinforcing filler TCRF4 in the form of flakes, sheets, particles or fibres has an average diameter of from about 0.5 μm to about 25 μm, from about 1 μm to about 24 μm, from about 2 μm to about 24 μm, from about 4 μm to about 22 μm, from about 6 μm to about 20 μm, from about 8 μm to about 18 μm, from about 10 μm to about 16 μm, or from about 12 μm to about 14 μm.

In various embodiments, the fourth reinforcing filler TCRF4 in the form of fibres has a length of greater than 1 μm, greater than 5 μm, greater than 10 μm, greater than 15 μm, greater than 20 μm, or greater than 25 μm.

In one embodiment, the fourth reinforcing filler TCRF4 in the form of flakes, sheets, particles has an average diameter, particle size, or thickness in the range 1 μm to 20 μm. In another embodiment, the fourth reinforcing filler TCRF4 in the form fibres has a length greater than 10 μm.

In various embodiments, the fourth reinforcing filler TCRF4 has an intrinsic thermal conductivity of at least 50 W/mK, at least 55 W/mK, at least 60 W/mK, at least 65 W/mK, at least 70 W/mK, at least 75 W/mK, at least 80 W/mK, at least 85 W/mK, at least 90 W/mK, at least 95 W/mK, at least 100 W/mK, at least 105 W/mK, at least 110 W/mK, at least 115 W/mK, or at least 120 W/mK.

In one embodiment, the fourth reinforcing filler TCRF4 has an intrinsic thermal conductivity of more than 100 W/mK.

In various embodiments, the fourth reinforcing filler TCRF4 has a volume electrical resistivity of less than 10⁻² ohm·cm, less than 10⁻³ ohm·cm, less than 10⁻⁴ ohm·cm, less than 10⁻⁵ ohm·cm, less than 10⁻⁶ ohm·cm, or less than 10⁻⁷ ohm·cm.

In one embodiment, the fourth reinforcing filler TCRF4 has a volume electrical resistivity of less than 10⁻³ ohm·cm.

In various embodiments, the fourth reinforcing filler TCRF4 has a breaking strength of more than 50 MPa, more than 75 MPa, more than 100 MPa, more than 125 MPa, more than 150 MPa, more than 175 MPa, more than 200 MPa, more than 225 MPa, more than 250 MPa, more than 275 MPa, or more than 300 MPa.

In one embodiment, the fourth reinforcing filler TCRF4 has a breaking strength of more than 200 MPa.

In various embodiments, the fourth reinforcing filler TCRF4 includes but is not limited to carbon fibre, carbon nanotubes (CNT), gold, silver, copper, nickel or a combination thereof.

In one embodiment, the fourth filler TCRF4 consists one or more materials selected from the group consisting of carbon fibre, carbon nanotubes (CNT), gold, silver, copper and nickel.

In various embodiments, the fourth reinforcing filler TCRF4 is present in a heat sink in an amount of from about 1% to about 10% by weight of the heat sink, from about 2% to about 10% by weight of the heat sink, from about 4% to about 10% by weight of the heat sink, from about 6% to about 10% by weight of the heat sink, or from about 8% to about 10% by weight of the heat sink.

In one embodiment, the first filler TCF1 is present in a heat sink in an amount from about 1% to about 20% by weight of the heat sink, the second filler TCF2 is present in a heat sink in an amount from about 1% to about 20% by weight of the heat sink, the third filler TCF3 is present in a heat sink in an amount from about 1% to about 20% by weight of the heat sink, and the fourth reinforcing filler TCRF4 filler is present in a heat sink in an amount from about 1% to about 20% by weight of the heat sink.

In another embodiment, the first filler TCF1 is present in a heat sink in an amount from about 5% to about 10% by weight of the heat sink, the second filler TCF2 is present in a heat sink in an amount from about 5% to about 10% by weight of the heat sink, the third filler TCF3 is present in a heat sink in an amount from about 5% to about 10% by weight of the heat sink, and the fourth reinforcing filler TCRF4 is present in a heat sink in an amount from about 5% to about 10% by weight of the heat sink.

In various embodiments, one or more surface modification agents are provided in the formulation for a heat sink. The surface modification agent serves to facilitate a better wetting and coupling of the TCF1, TCF2, TCF3 and TCRF4 with the polymer resin to provide a homogeneous interface or improved interface adhesion between polymer resin with other fillers. Advantageously, this results in improved physical and mechanical properties. The surface modification agent also helps to reduce the melt viscosity and facilitate uniform dispersion of fillers. Preferably, the surface modification agent is configured to have relatively high thermal stability to survive the harsh conditions of common high volume melt processing such as extrusion, hot-melt mixing and injection moulding, which usually operate at temperatures above the glass transition temperature T_{g} or melting temperature Tₘ of the thermoplastic polymer.

In various embodiments, the formulation for a heat sink comprises one or more surface modifying agents. The surface modifying agent(s) are present in the heat sink in an amount of from about 0.1% to about 5% by weight of the heat sink, from about 0.5% to about 5% by weight of the heat sink, from about 1% to about 5% by weight of the heat sink, from about 2% to about 5% by weight of the heat sink, from about 3% to about 5% by weight of the heat sink, or from about 4% to about 5% by weight of the heat sink.

In one embodiment, the formulation of a heat sink as disclosed herein includes by weight from about 0.1% to about 5% of surface modifying agents.

In various embodiments, the surface modification agent includes but is not limited to Triton X-100; Octoxynol-9 toctylphenoxypolyethoxyethanol or Silane; γ-aminopropyl triethoxy silane) or combinations thereof.

### BRIEF DESCRIPTION OF FIGURES

FIG. 1A is a photograph showing the top view of an injection moulded heat sink specimen A (a circular disk for thermal conductivity measurement).

FIG. 1B is a photograph showing the top view of an injection moulded heat sink specimen B (a square slab for hardness measurement).

FIG. 1C is a photograph showing the top view of an injection moulded heat sink specimen C (a dog-bone shaped sample for tensile strength and modulus measurements).

FIG. 1D is a photograph showing the top view of an injection moulded heat sink specimen D (an elongated sample for 3-point bend and impact tests).

FIG. 2 is a graph showing the heat dissipation characteristics of a heat sink (Specimen A) over a time period of 120 s.

FIG. 3 is a schematic flowchart for illustrating a method of making a filler composition in an exemplary embodiment.

FIG. 4 is a schematic flowchart for illustrating a method of making a formulation for a heat sink in an exemplary embodiment.

### DETAILED DESCRIPTION OF FIGURES

Exemplary embodiments of the disclosure will be better understood and readily apparent to one of ordinary skill in the art from the following discussions and if applicable, in conjunction with the figures. It should appreciate that other modifications related to structural, electrical and optical changes may be made without deviating from the scope of the invention. Exemplary embodiments are not necessarily mutually exclusive as some may be combined with one or more embodiments to form new exemplary embodiments.

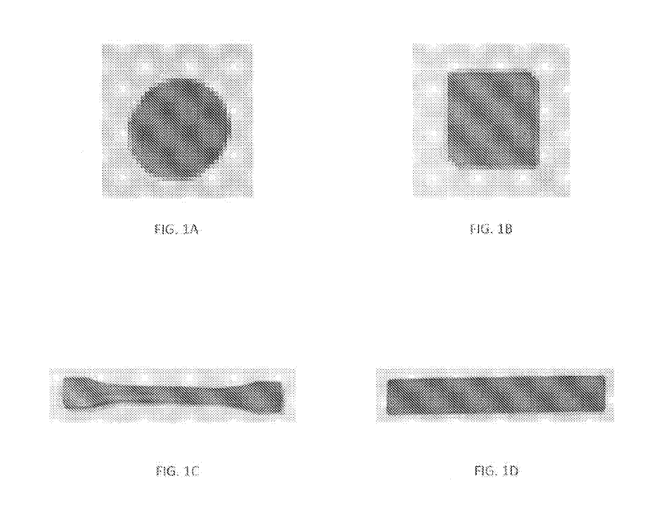

FIG. 1A is a photograph showing the top view of an injection moulded heat sink specimen A (a circular disk for thermal conductivity measurement). Specimen A has a diameter of about 12.7 mm and a thickness of either 1 mm or 3 mm. FIG. 1B is a photograph showing the top view of an injection moulded heat sink specimen B (a square slab for hardness measurement). Specimen B has a length of about 12.7 mm and a thickness of either 1 mm or 3 mm. FIG. 1C is a photograph showing the top view of an injection moulded heat sink specimen C (a dog-bone shaped sample for tensile strength and modulus measurements). Specimen C has a gauge length of about 50 mm, width of about 5 mm and thickness of about 2.13 mm. FIG. 1D is a photograph showing the top view of an injection moulded heat sink specimen D (an elongated sample for 3-point bend and impact tests). Specimen D has a length of about 60 mm, width of about 10 mm and thickness of about 1.12 mm.

All the four specimens A to D are prepared using the formulation as described herein, the formulation comprising a thermoplastic polymer matrix, a first thermally conductive filler, a second thermally conductive filler, a third thermally conductive filler, and a fourth thermally conductive reinforcing filler and coupling agents. The specimens A to D are subsequently subjected to various tests to characterize their properties.

### Hot Melt Mixing and Injection Moulding

The exemplary samples as described herein are prepared by Hot-Melt Mixing and Injection Moulding methods. The process parameters used in the present disclosure for Hot-Melt Mixing and Injection Moulding are as follows:

### Hot Melt Mixing—

### Temperature: 100° C. to 450° C.

### Duration: 15 min to 120 min

### Speed: 10 rpm to 100 rpm

### Injection Moulding—

Cylinder temperature: 200° C. to 450° C.
Mould temperature: 50° C. to 200° C.
Injection pressure: 200 bar to 1200 bar

### Thermal Conductivity

All samples as described herein are prepared by Hot-Melt Mixing and Injection Moulding into disks of 12.7 mm or square of 12.7 mm and with a thickness of either 1 mm or 3 mm. The thermal conductivity of a composition, as described herein, is tested according to ASTM E1461 in cross-plane (sample thickness) direction.

### Tensile Strength and Young's Modulus

All samples as described herein are prepared by Hot-Melt Mixing and Injection Moulding into dog-bone shaped samples of gauge length 50 mm, width of 5.0 mm and with a thickness of 2.13 mm. The tensile strength and Young's modulus of a composition, as described herein, are tested according to ASTM D368.

### Shore D Hardness

All samples as described herein are prepared by Hot-Melt Mixing and Injection Moulding into disks of 12.7 mm or square of 12.7 mm and with a thickness of either 1 or 3 mm. The hardness of a composition, as described herein, is tested according to ASTM D2240.

### Resistivity

All samples as described herein are prepared by Hot-Melt Mixing and Injection Moulding into disks of 12.7 mm or square of 12.7 mm and with a thickness of either 1 or 3 mm. The resistivity of a composition, as described herein, is tested according to ASTM D257 & D2739.

### IR Thermal Imaging Analysis

All samples as described herein are prepared by Hot-Melt Mixing and Injection Moulding into disks of 12.7 mm or square of 12.7 mm and with a thickness of either 1 mm or 3 mm. The IR thermal imaging analysis of a composition, as used herein, is tested according to ASTM E1311-14 or E1316-10b or E1862-97.

### Heat Dissipation

All samples as described herein are prepared by Hot-Melt Mixing and Injection Moulding into disks of 12.7 mm or square of 12.7 mm and with a thickness of either 1 mm or 3 mm.

The samples were preheated to 100° C. and allowed to cool naturally by mounting on a thermally insulative surface. The surface temperatures of the specimens were measured at different time points.

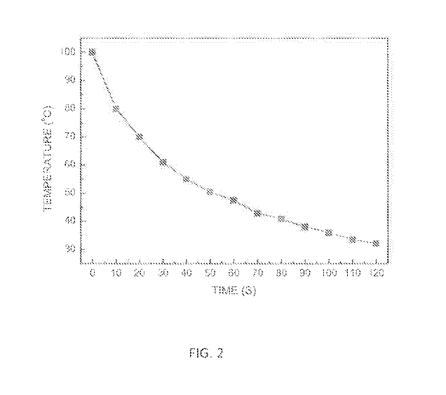

FIG. 2 is a graph showing the heat dissipation characteristics of a heat sink (Specimen A) over a time period of 120 s. At time t=Os, the surface temperature measured in the heat sink is about 100° C. At time t=60 s, the surface temperature measured in the heat sink is about 47.5° C. At time t=120 s, the surface temperature measured in the heat sink is 32° C. As shown, the plastic heat sink exhibit efficient heat dissipation and the temperature drops by more than 65° C. to ambient temperatures in less than 120 s.

The following examples as shown in Table 1 are put forth so as to provide those of ordinary skill in the art with complete disclosure and description of how the plastic heat sink, compositions, articles, devices, and/or methods described and claimed herein are made and evaluated, and are not intended to limit the scope of this invention. Unless otherwise indicated in the following examples and elsewhere in the specification and claims, all parts and percentages are by weight; temperatures are in degrees centigrade or at ambient temperature and pressures are at or near atmospheric conditions.

TABLE 1

| | | | | | Thermal | | | |
|---|---|---|---|---|---|---|---|---|
| | | | | | Conductivity | | | |
| | | | | | of the plastic | Tensile | Young's | |
| Sample | | Polymer | | Filler* | heat sink | Strength | Modulus | Shore D |
| Code | Polymer | Wt % | Fillers | Wt % | (W/mK) | (MPa) | (GPa) | Hardness |
| 225G1 | PC-ABS | 65 | TCF1, | 35 | 6 | 70 | 1.5 | 70 |
| | | | TCF2, | | | | | |
| | | | TCF3& | | | | | |
| | | | TCRF4 | | | | | |
| 234 | PC-ABS | 35 | TCF1, | 65 | 21.5 | 60 | 1.4 | 70 |
| | | | TCF2, | | | | | |
| | | | TCF3& | | | | | |
| | | | TCRF4 | | | | | |
| 233 | PC-ABS | 25 | TCF1, | 75 | 52 | 70 | 1.5 | 70 |
| | | | TCF2, | | | | | |
| | | | TCF3& | | | | | |
| | | | TCRF4 | | | | | |
| 152 | PC-ABS | 25 | TCF1, | 75 | 37.3 | 70 | 1.5 | 70 |
| | | | TCF2, | | | | | |
| | | | TCF3& | | | | | |
| | | | TCRF4 | | | | | |
| 118 | HDPE | 25 | TCF1, | 75 | 38.2 | 26 | 0.56 | 60 |
| | | | TCF2, | | | | | |
| | | | TCF3& | | | | | |
| | | | TCRF4 | | | | | |
| 227 | HDPE | 65 | TCF1, | 35 | 3.9 | 21 | 0.9 | 60 |
| | | | TCF2, | | | | | |
| | | | TCF3& | | | | | |
| | | | TCRF4 | | | | | |
| 232 | PEI | 65 | TCF1, | 35 | 7.4 | 87 | 1.7 | 77 |
| | | | TCF2, | | | | | |
| | | | TCF3& | | | | | |
| | | | TCRF4 | | | | | |

*The concentration of the individual filler varies from 1.0 wt % to 25.0 wt % by weight of the filler composition.

In Table 1, surface modification agent(s) are present in small quanities in the filler composition and are part of Filler Wt % in amount from about 0.1 wt % to about 5.0 wt % of the filler composition.

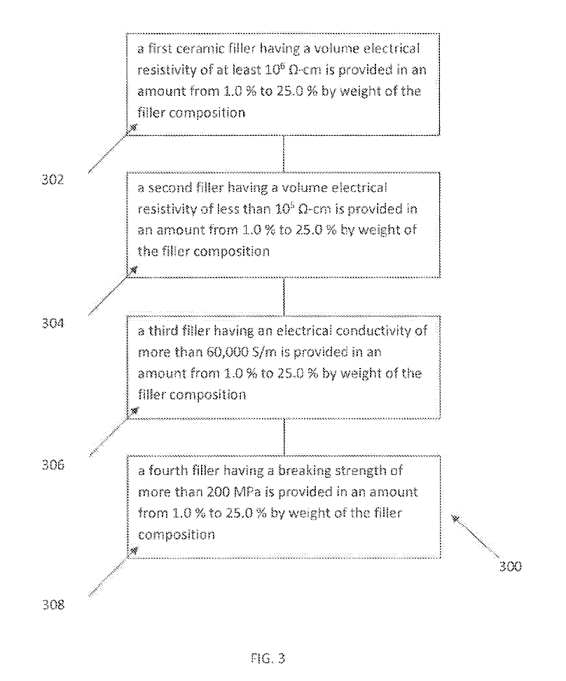

FIG. 3 is a schematic flowchart 300 for illustrating a method of making a filler composition in an exemplary embodiment. At step 302, a first ceramic filler having a volume electrical resistivity of at least 10⁶ Ω-cm is provided in an amount from 1.0% to 25.0% by weight of the filler composition. At step 304, a second filler having a volume electrical resistivity of less than 10⁵ Ω-cm is provided in an amount from 1.0% to 25.0% by weight of the filler composition. At step 306, a third filler having an electrical conductivity of more than 60,000 S/m is provided in an amount from 1.0% to 25.0% by weight of the filler composition. At step 308, a fourth filler having a breaking strength of more than 200 MPa is provided in an amount from 1.0% to 25.0% by weight of the filler composition.

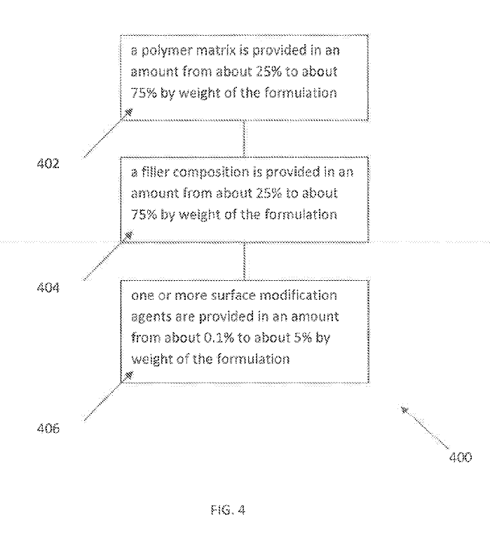

FIG. 4 is a schematic flowchart 400 for illustrating a method of making a formulation for a heat sink in an exemplary embodiment. At step 402, a polymer matrix is provided in an amount from about 25% to about 75% by weight of the formulation. At step 404, a filler composition is provided in an amount from about 25% to about 75% by weight of the formulation. At step 406, one or more surface modification agents are provided in an amount from about 0.1% to about 5% by weight of the formulation.

### Applications

Embodiments of the formulation and filler composition disclosed herein provide a heat sink for high power electronic devices, the heat sink exhibiting excellent through-plane thermal conductivity, mechanical strength, is electrically insulative, temperature resistant and injection moldable. Embodiments of the disclosed formulation and filler composition also seek to overcome the problems of plastic heat sinks known in the art.

The inventors have recognized that problems of wetting have to be overcome in order to achieve excellent cross-plane thermal conductivity and optimum physical properties of moldable plastic heat sink while being light-weight and relatively low in manufacturing costs. Prior art compositions are inadequate to address the needs of high cross-plane thermal conductivity and structural integrity in the same composition.

The ability of a plastic heat sink to dissipate heat is determined by its thermal conductivity. Thermal conductivity (k) is one of the basic thermophysical properties which determine the heat flux and the resulting temperature field in a device configuration, subject to boundary conditions and material properties.

The determination of thermal conductivity along the thickness direction that is the cross-plane or through-plane direction, which is perpendicular to the plane of heat sink, determines the bulk heat dissipation property of the material. On the other hand, the in-plane direction, which is parallel to the plane of the heat sink encounters challenges in achieving efficient heat dissipation of the absorbed heat by the heat sink material.

It has been recognised in a number of experimental data from existing literature that the cross-plane thermal conductivity is much lower (about four times lower) than the in-plane thermal conductivity. It is believed that this is attributed to the difference in electron and phonon transports for both cases. Thus, exemplary embodiments of the present disclosure provide plastic heat sinks which exhibit a higher cross-plane thermal conductivity to effectively absorb and dissipate the heat generated by the high power electronic devices to enhance their performance and reliability.

Thermally conductive plastic heat sinks made using exemplary formulations as disclosed herein are based on high performance polymer nanocomposites. These plastic heat sinks are capable of replacing metal components used in high power electronics, electric devices (motors, generators, power sources) and heat exchangers due to their excellent properties such as thermal conductivity, mechanical strength, light weight, corrosion resistance and ease of processing and design.

The inventors have recognised that by implementing suitable addition of hybrid fillers and control of process parameters using hot melt mixing and injection molding techniques, the characteristics of the plastic heat sinks can be improved significantly. For example, characteristics such as tunable thermal, electrical and mechanical properties exhibiting enhanced mechanical strength and thermal conductivities with desirable heat absorption and dissipation functions, can be achieved. Experimental data as disclosed herein have demonstrated that the choice of fillers, effective formulation and optimum process conditions facilitate fabrication of thermally conductive plastic heat sinks based on nanocomposite components that are capable of to removing heat and preventing electronic systems from heat related failures.

Advantageously, various embodiments of a formulation for a heat sink as disclosed herein provide a cost effective moldable thermoplastic heat sink that displays excellent thermal conductivity, mechanical strength, heat resistance and electrical resistance. The polymer matrix materials disclosed herein are common polymers or resins which are used in manufacturing industries for making a variety of products and hence there is no particular requirement of modifications of existing equipment or tools used in their fabrication. The plastic matrix, fillers and coupling agents can be melt processed using Hot-Melt Mixer methods and custom-designed heat sink components can be fabricated in high speed, high volume injection molding methods. The developed formulation(s) can be fabricated into custom designed products of varying size and shape (disks, plates, tubes, filaments and sheets) using compression molding, extrusion and injection molding manufacturing methods.

Even more advantageously, various embodiments of a formulation for a heat sink as disclosed herein provide a plastic heat sink which displays a high cross-plane thermal conductivity of at least 50 W/mK. In addition to displaying a high cross-plane thermal conductivity, the heat sink also exhibit desirable mechanical, thermal and heat absorption and dissipation characteristics such as enhanced tensile strength of more than 65 MPa; Young's Modulus of more than 1.4 Gpa; Shore D Hardness of more than 75, better resistance to heat of more than 150° C. and efficient heat dissipation characteristics of about 50% loss of absorbed heat in less than 60 s.

It will be appreciated by a person skilled in the art that other variations and/or modifications may be made to the embodiments disclosed herein without departing from the spirit or scope of the disclosure as broadly described. The present embodiments are, therefore, to be considered in all respects to be illustrative and not restrictive.

Additionally, when describing some embodiments, the disclosure may have disclosed a method and/or process as a particular sequence of steps. However, unless otherwise required, it will be appreciated that the method or process should not be limited to the particular sequence of steps disclosed. Other sequences of steps may be possible. The particular order of the steps disclosed herein should not be construed as undue limitations. Unless otherwise required, a method and/or process disclosed herein should not be limited to the steps being carried out in the order written. The sequence of steps may be varied and still remain within the scope of the disclosure.

1. A filler composition for a heat sink, the filler composition comprising
a first ceramic filler having a volume electrical resistivity of at least 10⁶ Ω-cm;
a second filler having a volume electrical resistivity of less than 10⁵ Ω-cm;
a third filler having an electrical conductivity of more than 60,000 S/m; and
a fourth filler having a breaking strength of more than 200 MPa.

2. The filler composition of claim 1, wherein
the first filler is present in an amount from 1.0% to 25.0% by weight of the filler composition;
the second filler is present in an amount from 1.0% to 25.0% by weight of the filler composition;
the third filler is present in an amount from 1.0% to 25.0% by weight of the filler composition; and
the fourth filler is present in an amount from 1.0% to 25.0% by weight of the filler composition.

3. The filler composition of claim 1, wherein the first filler has an intrinsic thermal conductivity of 10 W/mK to 50 W/mK; and
the second, third and fourth fillers have an intrinsic thermal conductivity of more than 100 W/mK.

4. The filler composition of claim 1, wherein the first ceramic filler is in the form of powder, agglomerates or fibres having an average particle size of 0.05 μm to 1000 μm.

5. The filler composition of claim 1, wherein the first filler comprises one or more ceramic fillers selected from the group consisting of boron nitride (BN), aluminium nitride (AlN), titanium nitride (TiN), aluminium oxide (Al₂O₃), zinc oxide (ZnO) and silicon carbide (SiC).

6. The filler composition of claim 1, wherein the second filler comprises one or more material selected from the group consisting of graphite, graphene, graphitized carbon black, carbon fibre and carbon nanotubes (CNT).

7. The filler composition of claim 1, wherein the second filler is in the form of flakes, sheets or fibres, having an aspect ratio of at least 25:1.

8. The filler composition of claim 1, wherein the third filler comprises one or more material selected from the group consisting of graphite, graphene, graphitized carbon black, carbon fibre and carbon nanotubes (CNT).

9. The filler composition of claim 1, wherein the third filler is in the form of nanoplatelets having a diameter of 1 μm to 20 μm and a thickness of 2 nm to 20 nm.

10. The filler composition of claim 1, wherein the fourth filler has a volume electrical resistivity of less than 10⁻³ Ω-cm.

11. The filler composition of claim 1, wherein the fourth filler comprises one or more material selected from the group consisting of carbon fibre, carbon nanotubes (CNT), gold, silver, copper and nickel.

12. The filler composition of claim 1, wherein the fourth filler is in the form of flakes, sheets or particles having a diameter/particle size/thickness from 1 μm to 20 μm, or in the form of fibres having a length of more than 10 μm.

13. A method of making a filler composition, the method comprising,
providing a first ceramic filler having a volume electrical resistivity of at least 10⁶ Ω-cm in an amount from 1.0% to 25.0% by weight of the filler composition;
providing a second filler having a volume electrical resistivity of less than 10⁵ Ω-cm in an amount from 1.0% to 25.0% by weight of the filler composition;
providing a third filler having an electrical conductivity of more than 60,000 S/m in an amount from 1.0% to 25.0% by weight of the filler composition;
providing a fourth filler having a breaking strength of more than 200 MPa in an amount from 1.0% to 25.0% by weight of the filler composition; and
blending the first to fourth fillers to obtain the filler composition.

14. A formulation for a heat sink, the formulation comprising,
a polymer matrix present in an amount from 25% to 75% by weight of the formulation;
a filler composition comprising a first ceramic filler having a volume electrical resistivity of at least 10⁶ Ω-cm, a second filler having a volume electrical resistivity of less than 10⁵ Ω-cm, a third filler having an electrical conductivity of more than 60,000 S/m, and a fourth filler having a breaking strength of more than 200 MPa, said filler composition present in an amount from 25% to 75% by weight of the formulation; and
a surface modifying agent present in an amount from 0.1% to 5% by weight of the formulation.

15. The formulation of claim 14, having a cross-plane thermal conductivity of at least 50 W/mK.

16. The formulation of claim 14, having a tensile strength of more than 20 MPa, a Young's modulus of more than 0.5 GPa and a Shore D hardess of more than 70.

17. The formulation of claim 14, wherein the polymer matrix comprises a thermoplastic polymer having a thermal conductivity of at least 0.17 W/mK.

18. The formulation of claim 17, wherein the thermoplastic polymer has a volume electrical resistivity at least 10¹⁵ Ω-cm.

19. The formulation of claim 17, wherein the thermoplastic polymer is an amorphous material having a glass transition temperature (T_{g}) of at least −80° C., or a crystalline material having a melting point (Tₘ) of at least 100° C.

20. The formulation of claim 17, wherein the thermoplastic polymer has a tensile strength of at least 20 MPa, and a Young's modulus of at least 1 GPa.
